(19) United States
(12) Patent Application Publication
(10) Pub. No.: US 2009/0258186 A1
(43) Pub. Date: Oct. 15, 2009

(54) WAFER-LEVEL METHOD FOR FABRICATING AN OPTICAL CHANNEL AND APERTURE STRUCTURE IN MAGNETIC RECORDING HEAD SLIDERS FOR USE IN THERMALLY-ASSISTED RECORDING (TAR)

(75) Inventors: Robert E. Fontana, JR., San Jose, CA (US); Jordan Asher Katine, Mountain View, CA (US); Neil Leslie Robertson, Palo Alto, CA (US); Barry Cushing Stipe, San Jose, CA (US); Timothy Carl Strand, San Jose, CA (US); Bruce David Terris, Sunnyvale, CA (US)

Correspondence Address: THOMAS R. BERTHOLD, 18938 CONGRESS JUNCTION COURT, SARATOGA, CA, 95070, US

(73) Assignee: HITACHI GLOBAL STORAGE TECHNOLOGIES NETHERLANDS B. V., San Jose, CA (US)

(21) Appl. No.: 12/101,066

(22) Filed: Apr. 10, 2008

(51) Int. Cl. G03F 7/00; B32B 3/10

(52) U.S. Cl. 428/131; 430/324

(57) ABSTRACT

A process for forming a plurality of sliders for use in thermally-assisted recording (TAR) disk drives includes a wafer-level process for forming a plurality of aperture structures, and optionally abutting optical channels, on a wafer surface prior to cutting the wafer into individual sliders. The wafer has a generally planar surface arranged into a plurality of rectangularly-shaped regions. In each rectangular region a first metal layer is deposited on the wafer surface, followed by a layer of radiation-transmissive aperture material, which is then lithographically patterned to define the width of the aperture, the aperture width being parallel to the length of the rectangularly-shaped region. A second metal layer is deposited over the patterned layer of aperture material. The resulting structure is then lithographically patterned to define an aperture structure comprising aperture material surrounded by metal and having parallel radiation entrance and exit faces orthogonal to the wafer surface.

### TECHNICAL FIELD

This invention relates generally to a method for fabricating sliders that support the read/write heads in magnetic recording disk drives, and more particularly sliders used in thermally-assisted recording (TAR) disk drives.

### BACKGROUND OF THE INVENTION

In magnetic recording disk drives, the magnetic material (or media) for the recording layer on the disk is chosen to have sufficient coercivity such that the magnetized data bits are written precisely and retain their magnetization state until written over by new data bits. As the areal data density (the number of bits that can be recorded on a unit surface area of the disk) increases, the magnetic grains that make up the data bits can be so small that they can be demagnetized simply from thermal instability or agitation within the magnetized bit (the so-called “superparamagnetic” effect). To avoid thermal instabilities of the stored magnetization, media with high magneto-crystalline anisotropy (Kᵤ) may be required. However, increasing Kᵤ also increases the short-time switching field, H₀, which is the field required to reverse the magnetization direction, which for most magnetic materials is somewhat greater than the coercivity or coercive field measured on much longer time-scales. However, H₀ cannot exceed the write field capability of the recording head, which currently is limited to about 15 kOe for perpendicular recording.

Since it is known that the coercivity of the magnetic material of the recording layer is temperature dependent, one proposed solution to the thermal stability problem is thermally-assisted recording (TAR), wherein the magnetic material is heated locally to near or above its Curie temperature during writing to lower the coercivity enough for writing to occur, but where the coercivity/anisotropy is high enough for thermal stability of the recorded bits at the ambient temperature of the disk drive (i.e., the normal operating or “room” temperature). Several TAR approaches have been proposed, primarily for the more conventional longitudinal or horizontal recording, wherein the magnetizations of the recorded bits are oriented generally in-the-plane of the recording layer. However, TAR is also applicable for perpendicular recording, wherein the magnetizations of the recorded bits are oriented generally out-of-the-plane of the recording layer.

In TAR, it is important to avoid heating data tracks adjacent to the data track where data is to be written because the stray magnetic field from the write head can erase data previously recorded in the adjacent tracks. Also, even in the absence of a magnetic field, heating of adjacent data tracks accelerates the thermal decay over that at ambient temperature and thus data loss may occur. A proposed solution for this adjacent-track interference problem is the use of an optical channel with a small aperture that directs heat from a radiation source, such as a laser, to heat just the data track where data is to be written. This type of TAR disk drive is described in U.S. Pat. No. 5,583,727 and U.S. Pat. No. 6,982,844.

In conventional (non-TAR) disk drives, each read/write head is located on an air-bearing slider that is maintained in close proximity to its associated disk surface as the disks rotate. The films making up the read and write heads are deposited on a wafer containing a large number, e.g., 40,000, of rectangular regions arranged in rows, with each region ultimately becoming an individual slider. After formation of the read and write heads at the wafer level, the wafer is cut into rows and the rows cut into individual sliders. The sliders are then “lapped” in a plane perpendicular to the wafer surface, with this plane becoming the slider's air-bearing surface (ABS). However, for sliders used for TAR disk drives, the only proposed methods for forming an optical channel and/or aperture structure have been to fabricate the optical channel and/or aperture structure on the slider at the row level, i.e., after the wafer has been cut into rows, or at the individual slider level. These are costly and time-consuming methods.

What is need is a wafer-level process for forming optical channels and aperture structures on air-bearing sliders for use in TAR disk drives.

### SUMMARY OF THE INVENTION

The invention relates to a wafer-level process for forming a plurality of aperture structures, and optionally abutting optical channels, on a wafer surface prior to cutting the wafer into rows and individual sliders. The wafer has a generally planar surface arranged into a plurality of rectangularly-shaped regions, with the regions being arranged in parallel rows. In each rectangular region a first metal layer is deposited on the wafer surface, followed by a layer of radiation-transmissive aperture material, which is then lithographically patterned to define the width of the aperture, the aperture width being parallel to the length of the rectangularly-shaped region. A second metal layer is deposited over the patterned layer of aperture material. The resulting structure is then lithographically patterned to define an aperture structure comprising aperture material surrounded by metal and having parallel radiation entrance and exit faces orthogonal to the wafer surface. The process includes methods for forming a metal ridge along the length of the aperture parallel to the wafer surface, which results in the aperture exit face having a generally C-shape.

An optical channel may be formed in each rectangular region adjacent the aperture structure and abutting the aperture radiation entrance face. A layer of radiation-transmissive cladding material is deposited on the wafer surface, followed by a layer of radiation-transmissive optical channel material having a higher index of refraction than the cladding material. A second layer of cladding material is then deposited to surround the optical channel material.

The invention also relates to a wafer having a plurality of generally rectangular regions, with each region having formed on it an aperture structure and optionally an abutting optical channel.

For a fuller understanding of the nature and advantages of the present invention, reference should be made to the following detailed description taken together with the accompanying figures.

### BRIEF DESCRIPTION OF THE DRAWING

FIG. 1 is a sectional view through a portion of an air-bearing slider and associated perpendicular magnetic recording disk for a thermally-assisted recording (TAR) disk drive that uses an optical channel and aperture structure to direct heat to the recording layer of the disk.

FIG. 2 is an illustration of the radiation exit face of an aperture structure having a generally C-shape with a characteristic dimension “d”.

FIG. 3 is a perspective view of a portion of a wafer showing a plurality of generally rectangular regions.

FIG. 4 is a perspective view of an aperture structure on a rectangular region of the wafer.

FIGS. 5A-5J are illustrations of steps in the fabrication process for one embodiment of the aperture structure.

FIGS. 6A-6E are illustrations of steps in the fabrication process for another embodiment of the aperture structure.

FIGS. 7A-7D are illustrations of steps in the fabrication process for forming the optical channel abutting the aperture structure.

### DETAILED DESCRIPTION OF THE INVENTION

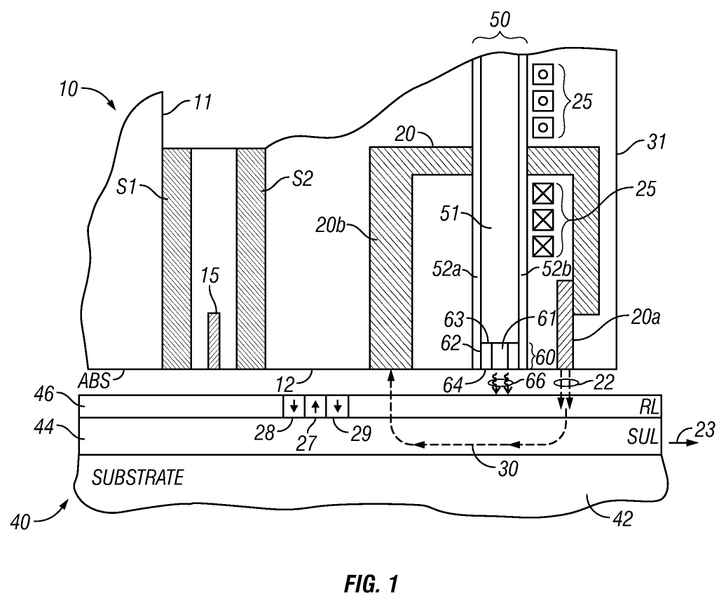

FIG. 1 is a sectional view through a portion of an air-bearing slider 10 and associated perpendicular magnetic recording disk for a TAR disk drive of the type that uses an optical channel for directing heat to the disk. The disk 40 includes a substrate 42, an optional “soft” relatively low-coercivity magnetically permeable underlayer (SUL) 44, and a perpendicular magnetic recording layer (RL) 46. The SUL 44 is not required for a TAR disk drive but if used is typically any alloy material suitable as the magnetically-permeable flux-return path, such as NiFe, FeAlSi, FeTaN, FeN, CoFeB and CoZrNb The RL 46 may be any media with perpendicular magnetic anisotropy, such as a cobalt-chromium (CoCr) alloy granular layer grown on a special growth-enhancing sublayer, or a multilayer of alternating films of Co with films of platinum (Pt) or palladium (Pd). The RL 46 may also be an L1₀ ordered alloy such as FePt or FeNiPt. The disk 40 would also typically include a protective overcoat (not shown) over the RL 46.

The slider 10 has a trailing surface 11 and an air-bearing surface (ABS) surface 12 oriented generally perpendicular to trailing surface 11. The slider 10 is typically formed of a composite material, such as a composite of alumina/titanium-carbide (Al₂O₃/TiC), and supports the read and write elements typically formed as a series of thin films and structures on its trailing surface 11. The surface 11 is called the trailing surface because of the direction 23 of the disk 40 relative to slider 10. The ABS 12 is the recording-layer-facing surface of the slider that faces the disk and is shown without the thin protective overcoat typically present in an actual slider. The recording-layer-facing surface or ABS shall mean the surface of the slider that is covered with a thin protective overcoat, the actual outer surface of the slider if there is no overcoat, or the outer surface of the overcoat. FIG. 1 is not drawn to scale because of the difficulty in showing the very small features.

The slider 10 supports a conventional magnetoresistive read head 15 located between shields S1 and S2, and a conventional perpendicular write head that includes a magnetic yoke 20 with a write pole 20a, a flux return pole 20b, and an electrically conductive coil 25. The write pole 20a is formed of conventional high-moment material, such as a FeCoNi alloy. The write coil 25 is shown as wrapped around yoke 20 with the electrical current directions being shown as into the paper by the coil cross-sections marked with an “X” and out of the paper by the coil cross-sections marked with a solid circle. When write-current pulses are directed through coil 25, the write pole 20a directs magnetic flux, represented by arrow 22, to the RL 46. The dashed line 30 with arrows show the flux return path through the SUL 44 back to the return pole 20b. As known in the art, the coil may also be of the helical type.

Because the disk drive is a TAR disk drive, the slider 10 also includes a waveguide or optical channel 50 with an aperture structure 60 near the ABS 12. The optical channel 50 with aperture structure 60 is depicted in FIG. 1 as extending through the yoke 20 and being located between the write pole 20a and the return pole 20b. However, for the method of fabrication of this invention, the optical channel 50 with aperture structure 60 may be fabricated on the trailing surface 11 at other locations, such as between shield S2 and return pole 20b, or between the write pole 20a and the outer face 31 of slider 10. The optical channel 50 is formed of a core material 51 such as a high-index-of-refraction dielectric material that is transmissive to radiation at the wavelength of the laser radiation source. Typical radiation-transmissive materials include TiO₂ and Ta₂O₅. The radiation-transmissive material 51 is surrounded by cladding material 52a, 52b that has a lower refractive index than the optical channel material 51 and is transmissive to radiation at the wavelength of the laser radiation source. Typical cladding materials include SiO₂ and Al₂O₃. The optical channel 50 directs radiation to the aperture structure 60. Aperture structure 60 includes the opening or aperture 61 that is filled with radiation-transmissive material and that is surrounded by metal layer 62. Preferably the aperture 61 is filled with a low index of refraction material such as SiO₂ or Al₂O₃. The aperture structure 60 has a radiation entrance face 63 and a radiation exit face 64 that are generally parallel to one another and to the ABS. The aperture structure 60 directs radiation, as represented by wavy arrow 66, to the RL 46 to heat the RL nearly to or above the Curie temperature of the material making up the RL. During writing, the RL 46 moves relative to the slider 10 in the direction shown by arrow 23. In TAR, heating from radiation through aperture structure 60 temporarily lowers the coercivity H_{c} of the RL 46 so that the magnetic regions may be oriented by the write field from write pole 20a. The magnetic regions become oriented by the write field if the write field H_{w} is greater than H_{c}. After a region of the RL in the data track has been exposed to the write field from the write pole 20a and heat from the aperture structure 60 it becomes written or recorded when it cools to below the Curie temperature. The transitions between recorded regions (such as previously recorded regions 27, 28 and 29) represent written data “bits” that can be read by the read head 15.

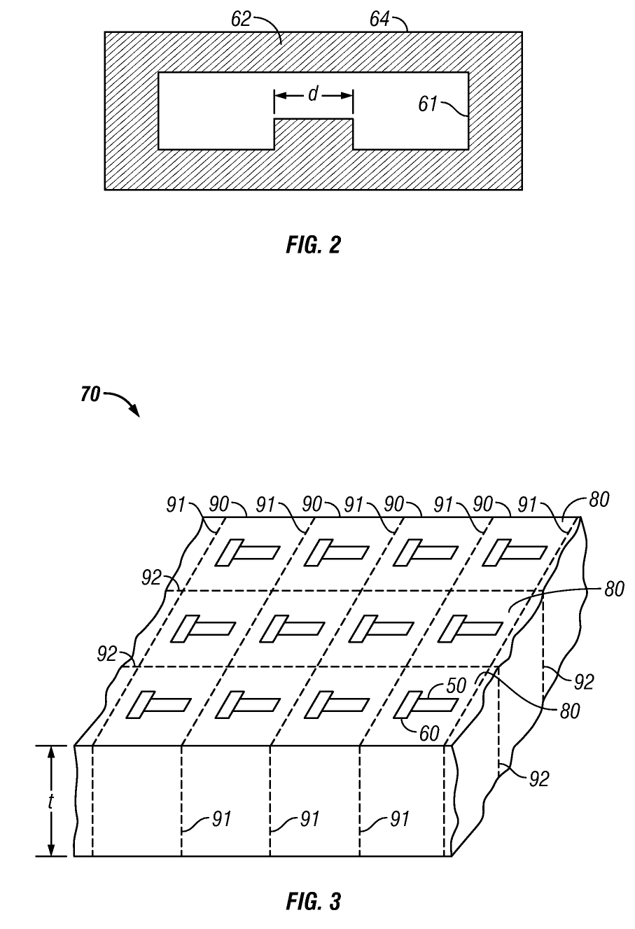

If the radiation source is light from a CD-RW type laser diode, then the wavelength is approximately 780 nm. The laser diode may be located on the slider 10. Alternatively, laser radiation may be delivered from a source off the slider through an optical fiber or waveguide. The aperture 61 at radiation exit face 64 acts as a near-field optical transducer. The aperture 61 is subwavelength-sized, i.e., the dimension of its smallest feature is less than the wavelength of the incident laser radiation and preferably less than one-half the wavelength of the laser radiation. FIG. 2 is a view of radiation exit face 64 with aperture 61 surrounded by metal 62. The aperture 61 shown in FIG. 2 is a “C”-shaped aperture with a characteristic dimension “d”. The near-field spot size is determined by the characteristic dimension “d”, which is the width of the ridge of the aperture. The resonant wavelength depends on the characteristic dimension of the aperture as well as the electrical properties and thickness of the thin film surrounding the aperture. This is discussed by J. A. Matteo et. al., Applied Physics Letters, Volume 85(4), pp. 648-650 (2004) for a C-shaped aperture.

For sliders used in conventional (non-TAR) disk drives, the films making up the read and write heads are deposited on a wafer containing a large number, e.g., 40,000, of rectangular regions arranged in rows, with each region ultimately becoming an individual slider and the wafer surface of each region becoming the trailing surface of the individual slider, like trailing surface 11 of slider 10. After formation of the read and write heads at the wafer level, the wafer is cut into rows and the rows cut into individual sliders. The sliders are then “lapped” in a plane perpendicular to the wafer surface, with this plane becoming the slider ABS. However, for sliders used for TAR disk drives, the only proposed methods for forming the aperture structures have been to fabricate the aperture structure on the slider at the row level, i.e., after the wafer has been cut into rows, or at the individual slider level. These are costly and time-consuming methods.

In the present invention, the aperture structures, as well as the optical channels, are fabricated at the wafer level. Thus, after the wafer is cut into rows and the rows into the individual sliders, each slider contains not only the read and write heads, but the aperture structure and optical channel required for TAR, like the slider shown in FIG. 1.

FIG. 3 is a perspective view of a portion of a wafer 70. The wafer 70 has a generally planar upper surface and a plurality of generally rectangular regions 80 arranged in generally parallel rows 90, with each region 80 being shown bounded by dashed lines 91, 92. Each region 80 has an optical channel 50 and aperture structure 60. After all the processing steps for forming the read and write heads, and the optical channels 50 and aperture structures 60 in the manner described below, the wafer 70 is cut into rows 90 along planes represented by dashed lines 91, and the rows 90 then cut along planes represented by dashed lines 92, to form the individual sliders. The sliders are lapped, either at the row level or the individual slider level, along planes parallel to planes represented by dashed lines 91, to define the ABS. The wafer 70 has a thickness “t” which is the “length” of the individual sliders.

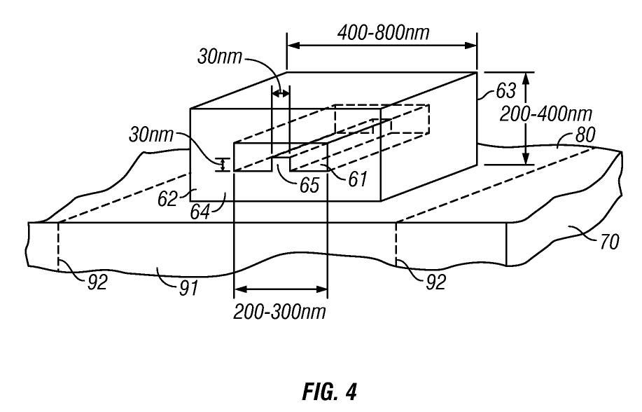

FIG. 4 is a perspective view, not to scale, of an aperture structure 60 on a rectangular region 80 of wafer 70. The aperture structure 60 includes the aperture 61 surrounded by metal 62, which may be a pure metal, such as Au or Cu, or an alloy of two or more metals, like a AuCu alloy. The aperture structure 60 has parallel faces 63, 64 that are generally parallel to the plane 91 along which the wafer will be cut into rows of rectangular regions. At faces 63 and 64, the aperture 61 has a generally C-shape defined by a ridge 65 of metal 62 that extends between faces 63 and 64. FIG. 4 also shows dimensions for the aperture structure 60, which are meant to be merely representative of typical dimensions and do not limit the scope of the invention. The aperture structure 60 has a width parallel to plane 91 and to the “length” of rectangular region 80 of about 400 to 800 nm and a thickness of about 200 to 400 nm in the direction perpendicular to the wafer surface. The ridge 65 has a width of about 30 nm and a thickness of about 30 nm, with the characteristic dimension “d” of the C-shaped aperture being the width of ridge 65. The size of the ridge 65 and the characteristic dimension “d” essentially define the spot size of the radiation incident on the recording layer, and for the dimensions shown the areal bit density on the disk would be greater than about 1 Terabit/in².

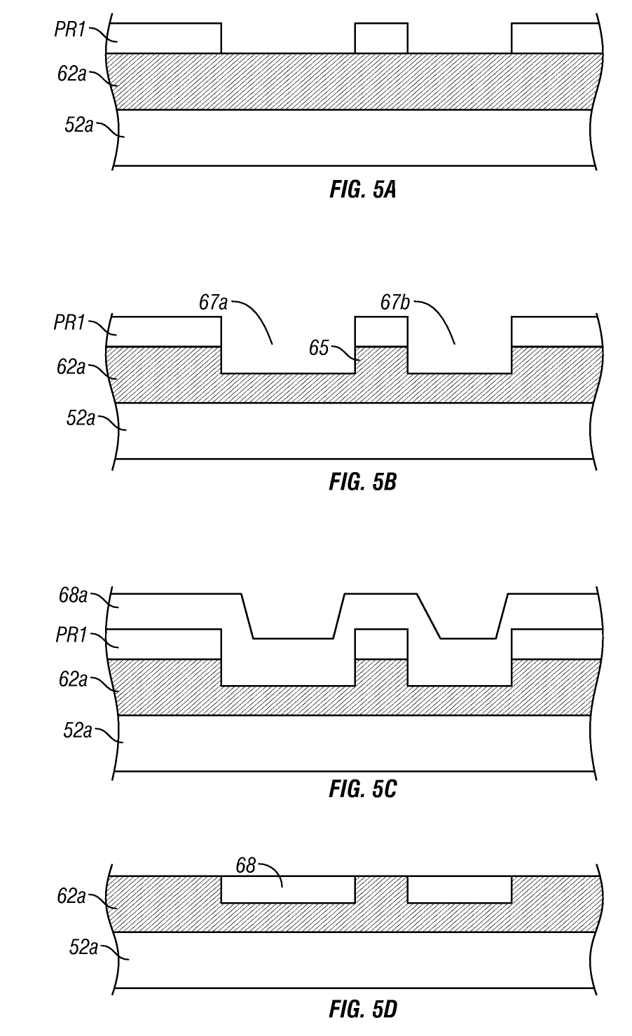

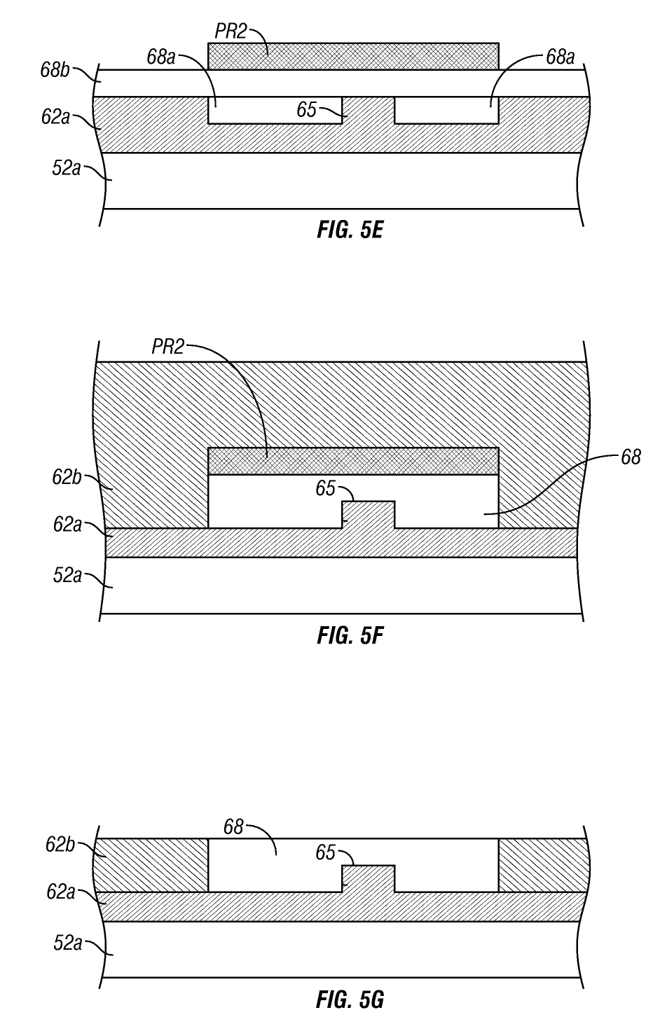

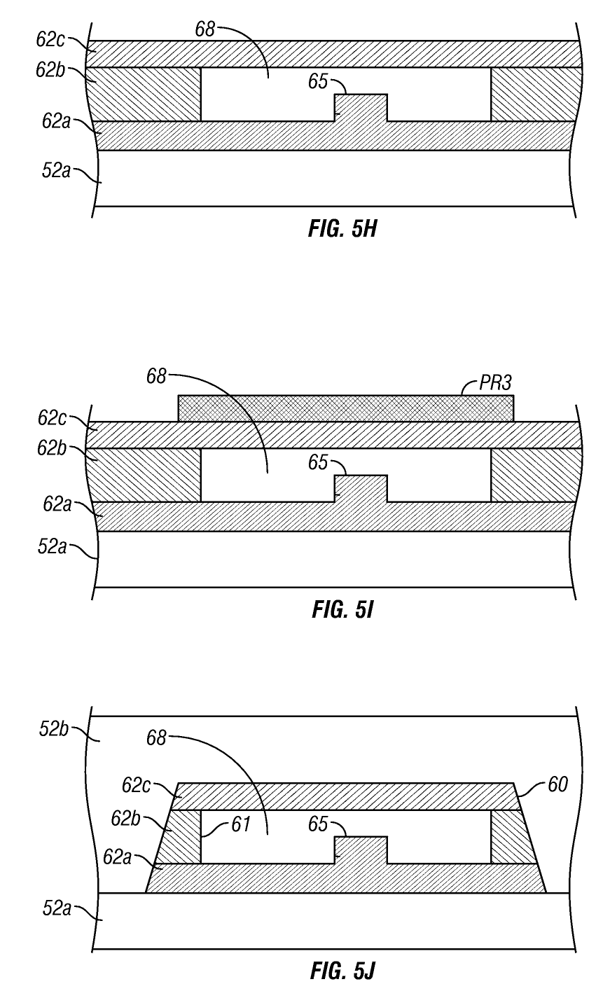

FIGS. 5A-5J show the steps in the fabrication process for one embodiment of the aperture structure 60 wherein the metal ridge is located on the bottom metal layer. In FIG. 5A, the substrate is a layer 52a of cladding material, such as SiO₂, which is formed on the wafer surface. For example, referring back to FIG. 1, the trailing surface 11 of slider 10 was the surface of wafer 70 before the slider 10 was cut from the wafer. After the shield S1, read head 15, shield S2, and flux return pole 20b are fabricated on the wafer, the layer 52a of cladding material is deposited. This layer becomes the substrate for the deposition, lithography and ion millings steps shown in FIGS. 5A-5J. In FIG. 5A, a first layer 62a of metal is deposited, followed by a first layer of photoresist (PR1) which is patterned to the desired shape. In FIG. 5B, timed ion milling is performed to form the depth of two trenches 67a, 67b separated by metal ridge 65. The height of the metal ridge 65, which forms the C-shape of the aperture, is controlled by the timed ion milling of the metal, for example Au, which mills at a known milling rate. In FIG. 5C, a first layer 68a of radiation-transmissive aperture material is deposited into the trenches 67a, 67b and over metal ridge 65. Next, in FIG. 5D, chemical-mechanical-polishing (CMP) is performed to remove PR1 and the material of layer 68a above it. In FIG. 5E, a second layer 68b of radiation-transmissive aperture material is deposited on the planarized surface over the metal ridge 65 and the material 68a in the trenches on opposite sides of the metal ridge 65. This dimension is about 30 nm and is controlled by the known deposition rates for the radiation-transmissive aperture material, such as SiO₂. A second photoresist layer (PR2) is then deposited and patterned with a dimension corresponding to the width of the aperture, e.g., approximately 200 nm. In FIG. 5F, ion milling has been performed over PR2 to remove unprotected portions of aperture material 68b. This is then followed by deposition of a second metal layer 62b, with a thickness of about 100 nm, over PR2. The aperture material 68 is shown as the assimilation of two layers 68a, 68b of the same material. In FIG. 5G, CMP is performed to remove PR2 and the portions of metal layer 62b above it as well as portions of metal layer 62b on the sides of the aperture structure. In FIG. 5H a third metal layer 62c, with a thickness of about 70 nm, is then deposited over the planarized surface. In FIG. 5I, a third layer of photoresist (PR3) is deposited and patterned to define the outer shape of the aperture structure. Ion milling is then performed with an endpoint at cladding layer 52a, followed by deposition of additional insulating material, shown as additional layer 52B of cladding material, resulting in the completed aperture structure shown in FIG. 5J. The resulting aperture structure 60, with metal ridge 65 in the lower portion of the surrounding metal, is depicted with the aperture 61 filled with radiation-transmissive aperture material 68, which is the result of the separate deposition of layers 68a, 68b of the same material.

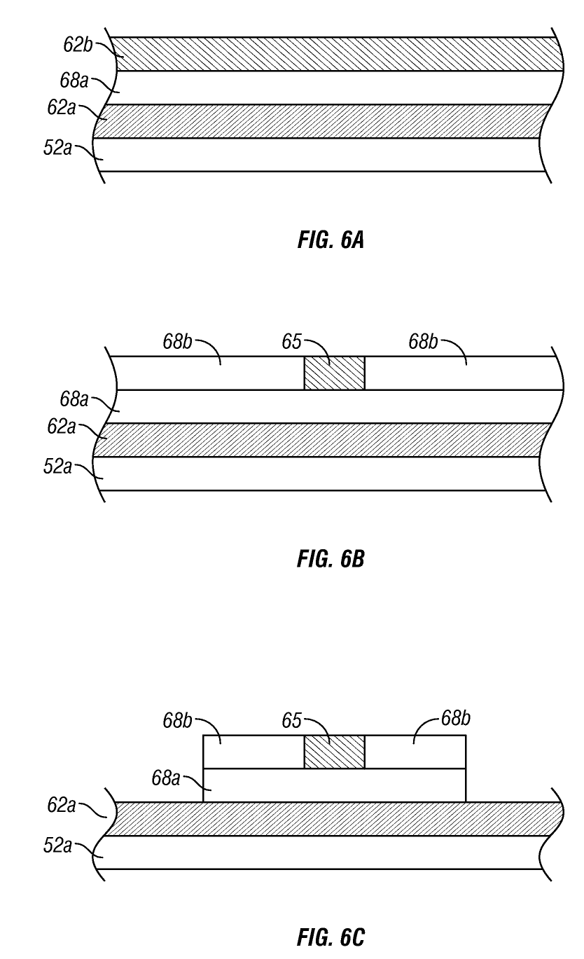

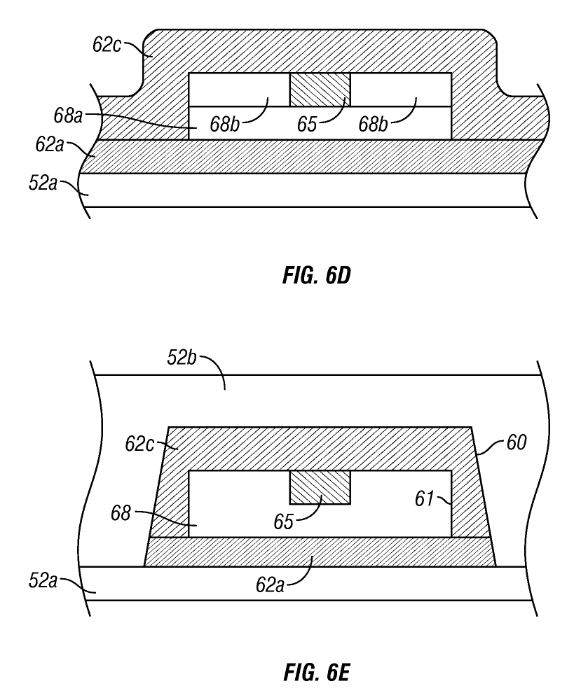

FIGS. 6A-6E show the steps in a fabrication process for an embodiment of the aperture structure in which the metal ridge 65 is formed in the upper metal layer. In FIG. 6A, the substrate is a layer 52a of cladding material, such as SiO₂, which is formed on the wafer surface. A first layer 62a of metal of about 70 nm thickness is deposited, followed by a first layer 68a of about 30 nm radiation transmissive aperture material, followed by a second layer 62b of about 30 nm of metal. The second metal layer 62b is then lithographically patterned, using electron-beam (e-beam) or other high resolution lithography, to define the metal ridge 65. Ion milling is then performed to remove the unprotected portions of metal layer 62b. This is followed by deposition of a second layer 68b of radiation-transmissive material to a thickness of about 30 nm over metal ridge 65 and on the first layer 68a. CMP is then performed, resulting in the structure shown in FIG. 6B. The structure of FIG. 6B is then lithographically patterned, using e-beam or other high resolution lithography, and etched by reactive ion etching (RIE) to remove unprotected portions of layers 68a, 68b, leaving the structure shown in FIG. 6C. In FIG. 6D, a third layer 62c of metal is deposited over the structure to a thickness of about 130 nm. The structure in FIG. 6D is then subjected to CMP to planarize the third metal layer 62c. This is followed by lithographic patterning to define the width of the aperture structure, and ion milling with an endpoint at cladding layer 52a, to remove unprotected portions of metal layers 62a, 62c. This is followed by deposition of additional insulating material, shown as additional layer 52b of cladding material, resulting in the completed aperture structure shown in FIG. 6E. The resulting aperture structure 60, with metal ridge 65 in the upper portion of the surrounding metal, is depicted with the aperture 61 filled with radiation-transmissive aperture material 68, which is the result of the separate deposition of layers 68a, 68b of the same material. The method shown in FIGS. 6A-6E has fewer CMP steps than the method of FIGS. 5A-5J. Also, the first layer 68a of aperture material, and the second metal layer 62b, which determines the height of the ridge 65, are deposited sequentially (see FIG. 6A), which improves the ability to control the thicknesses of these layers.

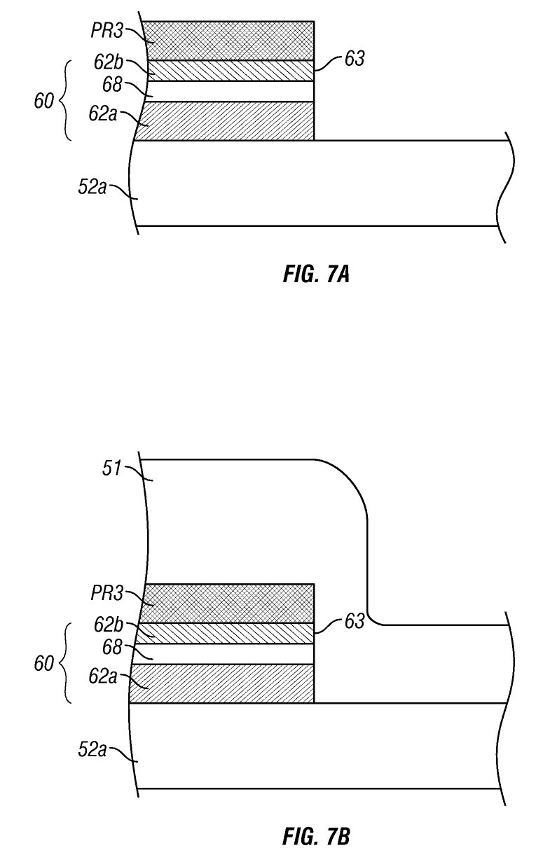

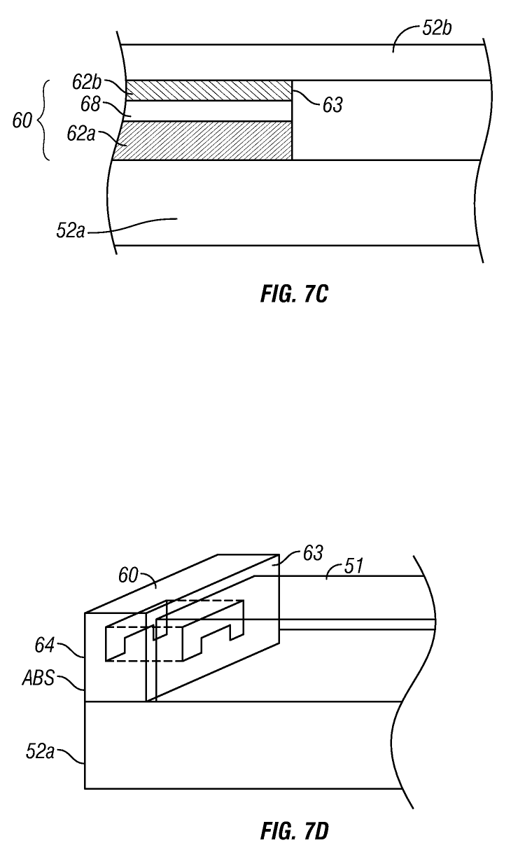

FIGS. 7A-7D shows the steps for forming the optical channel abutting the aperture structure. FIG. 7A shows the rear face 63 of aperture structure 60 that was formed by ion milling over PR3, using cladding layer 52a as the endpoint. In FIG. 7B a layer of radiation-transmissive material 51 for the optical channel is deposited over the structure of FIG. 7A and onto the cladding layer 52a. CMP is then performed and the outer layer of cladding material 52b is then deposited, leaving the structure shown in FIG. 7C. As shown in FIG. 7C, the optical channel 51 is abutted to end face 63 of aperture structure 60 and is surrounded by cladding material 52a, 52b. FIG. 7D is a perspective view of the aperture structure 60 with abutted optical channel 51, but is depicted without the outer cladding layer 52b to better illustrate the structure. In FIG. 7D, the wafer has been separated into rows and the rows lapped to define the ABS of the slider with the face 64 of aperture structure 60 essentially at the ABS. This also defines the length of the aperture structure 60 in the direction perpendicular to the ABS.

While the present invention has been particularly shown and described with reference to the preferred embodiments, it will be understood by those skilled in the art that various changes in form and detail may be made without departing from the spirit and scope of the invention. Accordingly, the disclosed invention is to be considered merely as illustrative and limited in scope only as specified in the appended claims.

What is claimed is:

1. A method for making a plurality of air-bearing sliders for use in thermally-assisted recording (TAR) comprising:
providing a wafer having a generally planar surface;
forming an aperture structure on each of a plurality of generally rectangularly-shaped regions on the wafer surface, the regions being arranged in generally parallel rows, said aperture-structure-forming comprising:
depositing a first metal layer;
depositing on the first metal layer a layer of aperture material substantially transmissive to radiation at a preselected wavelength;
lithographically patterning the layer of aperture material to define the width of the aperture, the aperture width being generally parallel to the length of the generally rectangularly-shaped region;
depositing a second metal layer over the patterned layer of aperture material; and
lithographically patterning the first metal layer, patterned layer of aperture material and second metal layer to define an aperture radiation entrance face generally orthogonal to the wafer surface.

2. The method of claim 1 further comprising, after depositing the first metal layer, lithographically patterning the first metal layer to form in the first metal layer two parallel trenches separated by a metal ridge, and wherein depositing the layer of aperture material comprises depositing the aperture material in the trenches and to a predetermined thickness on the ridge.

3. The method of claim 1 wherein depositing the layer of aperture material comprises depositing a first layer of aperture material to a predetermined thickness, and further comprising, after depositing the first layer of aperture material, forming on the first layer of aperture material a metal ridge and a second layer of aperture material on opposite sides of said ridge, and wherein depositing a second metal layer comprises depositing the second metal layer over the metal ridge and second layer of aperture material.

4. The method of claim 1 further comprising, on each region, forming an optical channel adjacent the aperture structure and abutting the aperture radiation entrance face, the optical-channel-forming comprising depositing optical channel material substantially transmissive to radiation at said wavelength and depositing on the optical channel material cladding material substantially transmissive to radiation at said wavelength and having a lower refractive index than the optical channel material.

5. The method of claim 4 further comprising depositing a layer of cladding material substantially transmissive to radiation at said wavelength and having a lower refractive index than the optical channel material on the wafer surface prior to forming the aperture structure.

6. The method of claim 4 further comprising cutting the wafer into rows of wafer regions, each region having an aperture structure and abutted optical channel.

7. The method of claim 6 further comprising lapping the rows along a plane generally parallel to the aperture radiation entrance faces to define an aperture radiation exit face on each aperture structure.

8. The method of claim 1 wherein the metal is selected from the group consisting of Au, Cu, and an alloy of Au and Cu.

9. The method of claim 1 wherein the aperture material is selected from the group consisting of SiO₂ and Al₂O₃, and the optical channel material is selected from the group consisting of TiO₂ and Ta₂O₅.

10. The method of claim 1 wherein the cladding material is selected from the group consisting of SiO₂ and Al₂O₃.

11. A method for making a plurality of air-bearing sliders for use in thermally-assisted recording (TAR) comprising:
(a) providing a wafer having a generally planar surface;
(b) forming an aperture structure on each of a plurality of generally rectangularly-shaped regions on the wafer surface, the regions being arranged in generally parallel rows, said aperture-structure-forming comprising:
depositing a first metal layer;
depositing on the first metal layer a first layer of aperture material substantially transmissive to radiation at a preselected wavelength;
forming a metal ridge on the first layer of aperture material;
depositing a second layer of aperture material substantially transmissive to radiation at said wavelength on the metal ridge and on the first layer of aperture material on opposite sides of the metal ridge;
planarizing the second layer of aperture material;
lithographically patterning the first and second layers of aperture material to define the width of the aperture, the aperture width being generally parallel to the length of the generally rectangularly-shaped region;
depositing a second metal layer over the patterned layer of aperture material; and
lithographically patterning the first metal layer, patterned layers of aperture material and second metal layer to define an aperture radiation entrance face generally orthogonal to the wafer surface; and
(c) forming an optical channel adjacent the aperture structure and abutting the aperture radiation entrance face, the optical-channel-forming comprising:
depositing optical channel material substantially transmissive to radiation at said wavelength on the aperture structure and the wafers surface adjacent the radiation entrance face; and
depositing on the optical channel material cladding material substantially transmissive to radiation at said wavelength and having a lower refractive index than the optical channel material.

12. The method of claim 11 further comprising depositing a layer of cladding material substantially transmissive to radiation at said wavelength and having a lower refractive index than the optical channel material on the wafer surface prior to forming the aperture structure and optical channel.

13. The method of claim 11 further comprising, after forming the aperture structure and optical channel in each region, (d) cutting the wafer into rows of wafer regions, each region having an aperture structure and abutted optical channel; and (e) lapping the rows along a plane generally parallel to the aperture radiation entrance faces to define an aperture radiation exit face on each aperture structure.

14. The method of claim 13 further comprising (f) cutting a wafer row into individual sliders, each slider having an aperture structure and abutted optical channel.

15. A wafer having a plurality of generally rectangularly-shaped regions arranged in rows, each region comprising:
a substrate having a generally planar surface;
an aperture structure on the substrate and comprising metal material on the substrate surface and having an aperture therein extending between first and second faces generally orthogonal to the substrate surface, and aperture material located within said aperture and being substantially transmissive to radiation at a preselected wavelength, the aperture at said first and second faces having a characteristic dimension less than said wavelength;
an optical channel on the substrate and comprising material substantially transmissive to radiation at said wavelength and having a face generally orthogonal to the substrate surface and abutting the second face of the aperture structure; and
cladding material substantially transmissive to radiation at said wavelength surrounding the optical channel and having a lower refractive index than the optical channel material.

16. The wafer of claim 15 wherein the aperture at said first and second aperture faces has a generally C-shape.

17. The wafer of claim 16 wherein said generally C-shape is defined by a ridge of said metal material extending between said first and second aperture faces.

18. The wafer of claim 15 wherein said metal material is selected from the group consisting of Au, Cu, and an alloy of Au and Cu.

19. The wafer of claim 15 wherein the aperture material is selected from the group consisting of SiO₂ and Al₂O₃, and the optical channel material is selected from the group consisting of TiO₂ and Ta₂O₅.

20. The wafer of claim 15 wherein the cladding material is selected from the group consisting of SiO₂ and Al₂O₃.
